(19) United States
(12) Patent Application Publication
(10) Pub. No.: US 2009/0026474 A1
(43) Pub. Date: Jan. 29, 2009

(54) RADIATION-EMITTING ELEMENT AND METHOD FOR PRODUCING A RADIATION-EMITTING ELEMENT

(75) Inventors: Simon Blumel, Schierling (DE); Bert Braune, Wenzenbach (DE)

Correspondence Address: FISH & RICHARDSON PC, P.O. BOX 1022, MINNEAPOLIS, MN, 55440-1022, US

(73) Assignee: OSRAM OPTO SEMICONDUCTORS GMBH, Regensburg (DE)

(21) Appl. No.: 12/067,834

(22) PCT Filed: Sep. 8, 2006
(86) PCT No.: PCT/DE2006/001571

§ 371 Date: Jul. 11, 2008

(30) Foreign Application Priority Data
Sep. 30, 2005 (DE) 10 2005 047 063.7
Jul. 13, 2006 (DE) 10 2006 032 428.5

(51) Int. Cl. H01L 33/00

(52) U.S. Cl. 257/98; 438/27; 257/E33.058

(57) ABSTRACT

A radiation-emitting component comprises an optical element and a housing body that has a fastening device that engages with or wraps around the optical element, wherein the fastening device is bent or is provided with projections in such a way that the optical element is irreversibly fixed on the housing body.

This invention relates to a radiation-emitting component that has an optical element and a housing body. The invention also relates to a method for producing such a component.

DE 199 45 675 A1 discloses a surface-mountable LED housing in which there is an LED chip. A lens that comprises a thermoplastic material follows the chip. The lens is fastened to an encapsulation of the chip.

In a lens that is fastened to a capsule, there is a risk of detachment. On the one hand, this can arise from low adhesion of a material used for the encapsulation, for example silicone, to the lens, or on the other hand low mechanical strength of an adhesive used can be the cause.

The task underlying this invention is to describe a radiation-emitting component that has a mechanically stable connection between an optical element and a housing body. This task is accomplished by a radiation-emitting component pursuant to patent claim 1.

It is also the purpose of this invention to describe a method for producing a radiation-emitting component that has a mechanically stable connection between an optical element and a housing body. This task is accomplished by a method pursuant to patent claim 18.

Advantageous refinements of the radiation-emitting component and versions of the method are described in the dependent claims.

A radiation-emitting component pursuant to the invention comprises an optical element and a housing body that has a fastening device that engages with or wraps around the optical element, wherein the fastening device is bent or provided with projections in such a way that the optical element is irreversibly fixed to the housing body.

Anchoring the optical element to the housing body by means of the fastening device makes possible a mechanically stable connection between the optical element and the housing body that is relatively insensitive to thermal or mechanical effects.

According to a preferred embodiment, the fastening device has the configuration of a wall that is bent so that it frames a projection of the optical element. The projection is made on a back face of the optical element facing the housing body and encircling it.

With special preference the fastening device extends out of a flat surface of the housing body, for example, and edges a radiation window of the housing body. One end of the fastening device facing the optical element is bent toward the optical element and surrounds it with a form fit. On the one hand, this irreversibly fixes the optical element on the housing body. On the other hand, this can produce a good seal of the radiation-emitting component from harmful media, for example gases or liquids, which makes the component more stable to aging.

A cross section of the fastening device, for example, has the shape of a circular or polygonal ring. In general, the shape of the fastening device matches that of the optical element, so that it surrounds the optical element with a form fit.

According to another preferred embodiment, the fastening device comprises at least two fastening elements. These can be in the form of pegs or combs. In this case, the optical element has recesses that correspond in size at least to the size of the fastening elements. The fastening elements are placed in the recesses or plugged into them.

It is especially preferred for the recesses to be through-holes. Then the fastening elements placed in the recesses can be bent around from the face of the optical element.

Cavities between the recesses and the fastening elements can be at least partially filled with a material that has a refractive index corresponding to that of the material of the optical element. Advantageously by this measure, optical characteristics of the optical element provided to configure radiation remain essentially unchanged.

According to a preferred configuration, the optical element is attached away from the housing body. In particular, a gap exists between the optical element and the housing body that compensates when heated for expansion of a material with a larger coefficient of expansion than surrounding materials. This can reduce the risk of cracking because of thermal stresses.

The housing body typically comprises at least one radiation-emitting semiconductor body that is placed in a recess and is embedded in a shell. Since the shell comprises material, for example silicone, that expands more strongly than the housing body or the optical element under the action of heat, for example from soldering or thermal forming, separation of the optical element and the housing body proves to be especially advantageous.

The radiation-emitting semiconductor body can be an LED, especially a thin-film LED chip.

A thin-film LED chip is distinguished in particular by at least one of the following characteristic features:
a reflective layer is applied or formed on a first principal surface of a radiation-generating sequence of epitaxial layers facing a carrier element, which reflects back to it at least a portion of the electromagnetic radiation generated in the sequence of epitaxial layers;
the sequence of epitaxial layers has a thickness in the range of 20 μm or less, particularly in the range of 10 μm; and
the sequence of epitaxial layers contains at least one semiconductor layer with at least one surface that has a blended structure that leads in the ideal case to an approximately ergodic distribution of the light in the epitactic sequence of epitaxial layers, i.e. it has the most ergodic possible stochastic scattering properties.

A basic principle of a thin-layer LED chip, for example, is described in I. Schnitzer et al., Appl. Phys. Lett. 63 (16), Oct. 18, 1993, 2174-2176, the disclosure content of which is incorporated herewith to that extent by back reference.

A thin-film LED chip is a Lambert surface radiator to a good approximation.

The recess in which the semiconductor body is placed can be funnel-shaped, and together with the optical element it can shape the radiation generated by the semiconductor body.

The radiation-emitting semiconductor body can emit radiation in the short-wave spectral range, particularly blue or ultraviolet.

A radiation-emitting, semiconductor body that has an active sequence of layers or at least one layer that comprises a nitride III/V compound semiconductor material, preferably AlₙGaₘIn₁₋ₙ₋ₘ N, wherein 0≦n≦1, 0≦m≦1 and n+nm≦1, is especially suitable for generating short-wave radiation. This material does not necessarily have to have a mathematically exact composition according to the formula above. Instead, it can have one or more dopants as well as additional constituents that do not essentially change the characteristic physical properties of the AlₙGaₘIn₁₋ₙ₋ₘN material. For simplicity, however, the formula above contains only the essential constituents of the crystal lattice (Al, Ga, In, N), even though these can also be replaced in part by small amounts of other substances.

A radiation-emitting component with such a semiconductor body is also suitable for emitting longer-wave radiation if a conversion element follows the semiconductor body in the direction of radiation to convert the short-wave radiation into longer-wave radiation. It is also suitable for generating mixed-color or “white” light by mixing radiation of different wavelengths.

The shell preferably contains particles of luminescence-converting materials for wavelength conversion. Suitable luminescence conversion materials, such as a YAG:Ce powder, are described, for example, in WO 98/12757, the content of which is incorporated herewith to that extent by back reference.

According to a preferred configuration, the housing body comprises a thermoplastic material. Since such material can be formed relatively well, the fastening device can be bent with little technical effort or thermal expense. It is especially preferred for the fastening device to be bent by means of a forming punch.

It is also possible for the housing body to comprise a ceramic material.

The optical element in particular comprises a material that provides its form stability at the temperature for processing the fastening device.

The optical element is also stable to cloudiness or discoloration under the action of radiation, particularly short-wave radiation. In particular, the optical element is made to be stable to the permanent action of short-wave radiation of relatively high intensity, such as can occur with high-power LED components, for example. The risk of the beam-forming properties or of the transmission of the optical element being changed by radiation during operation can be reduced overall in this way.

The optical element preferably comprises a silicone, silicone resin, a thermosetting material such as epoxy resin, or a hybrid material that contains silicone and epoxide.

In another preferred configuration of the radiation-emitting component, the optical element is a refractive element, a diffractive element, or a dispersive element. The beam is formed by refractive elements by refraction, optionally through a position-dependent index of refraction (GRIN: GRadient INdex), by diffractive elements by diffraction, and by dispersive elements by the wavelength-dependence of the index of refraction.

For example, the optical element is made as a lens, perhaps a diffractive or refractive lens, or a reflector, preferably with a focus or a focal range in each case, that is associated with the semiconductor body.

The fastening device can be made integral with the housing body. Alternatively, if different materials may be desired for the fastening device and for the housing body, the fastening device can be molded onto the housing body as a separate element.

The fastening device is preferably formed thermally, in other words the fastening device is bent or provided with projections under the influence of heat. It is particularly preferred to use a forming punch for this, with the fastening device being bent or provided with projections by stamping with the punch. The fastening device then prevents the optical element from becoming detached and the optical element is irreversibly fixed to the housing body.

The radiation-emitting device can also be made as an SMD (Surface Mount Device) component, as disclosed, for example, in the article “SIEMENS SMT-TOPLED for Surface Mounting” by F. Möllmer and G. Waitl (Siemens Components 29 (1991), Number 4, p. 147).

A method for producing a radiation-emitting component pursuant to the invention is described below. The radiation-emitting component can have the features mentioned in connection with the method, beyond the features already mentioned.

An optical element and a housing body that has a fastening device are made available by the method of the invention. The optical element is positioned relative to the housing body so that the fastening device engages in or wraps around the optical element. The fastening device is then formed so that the optical element is irreversibly fixed to the housing body. The fastening device is then bent or projections are formed on the fastening device.

According to a preferred configuration of the method, the fastening device is heated at least partially, so that it is plastic and can be formed, but cannot flow. It is particularly preferred for the fastening device to comprise a thermoplastic material, and suitable temperatures for forming the fastening device can lie in the range of the glass transition temperature, the melting point or the plasticizing temperature. Thermal forming, particularly riveting, hot-pressing, or tamping of the fastening device is preferably carried out using a forming punch or by other means.

Differentiation should be made when riveting between hot-form riveting, hot-stamping, and hot air riveting.

In the case of hot-form riveting, a heated punch heats the fastening device and bends it in the same production step under pressure, or forms a projection. The punch is then raised, and the formed fastening device can cool to room temperature. Material recovery of the formed fastening device can be kept low by setting the working temperature. In the case of amorphous thermoplastics, a suitable working temperature is below the glass transition temperature. In the case of partially crystalline plastics it is between the melting point and the glass transition temperature.

Hot-form riveting is advantageously a relatively economical method. The short processing times are especially advantageous.

In hot-press riveting, heat is introduced separately from the forming of the fastening device. The fastening device is first heated by a hotpunch. The fastening device is then formed and the projection is created with a cold punch. Although the punch temperature is usually above 300° C., less relaxation of the plastic can be achieved by a following cooling phase under pressure and form constraint than with hot-form riveting. Of course hot-press riveting entails a relatively long process time.

Hot air riveting operates contactlessly in the heating phase. A continuously circulating stream of hot air heats the fastening device. Here also, the heating takes place separately from the forming. Low relaxation of the plastic can be achieved here also by the following cooling phase under pressure and form constraint. The working temperature is usually higher than 300° C.

In hot-pressing the fastening device is formed by heating and mechanical force.

Thermal forming can be carried out before after mounting the radiation-emitting component, for example on a printed circuit board.

In a special configuration of the method, the housing body is produced by injection molding, high-pressure die casting, or high-pressure injection molding. Such methods are particularly suitable for economical high-volume production. The optical element can also be produced by injection molding, high-pressure die casting, or high-pressure injection molding.

In particular, the housing body and the optical element can be produced by means of 2K injection molding. According to a preferred variant, a conductor frame with the semiconductor body already mounted and wired is introduced into an injection molding form and a molding material is injected, so that an injection-molded housing body is formed. The optic element is injection-molded, onto the molding material of the housing body by subsequent injection molding, high-pressure die casting, or high-pressure injection molding, preferably soon, and with special preference while the molding material of the housing body is still hot. The optical element is consequently joined to the housing body with a form fit. Since oxidation of the molding material of the housing body is then still slight, good adhesion can be produced between the optical element and the housing body. This can advantageously strengthen the anchoring of the optical device on the housing body.

According to another preferred embodiment, the optical element is produced by 2K injection molding. This is advantageous in particular when the optical element has a projection or a base that comprises a material different from that of the base body.

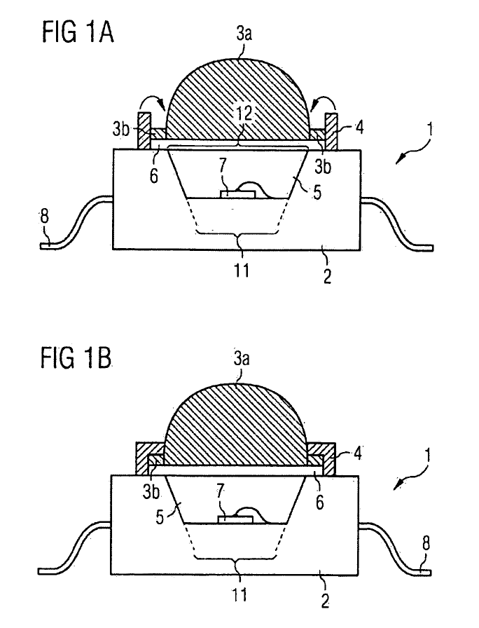

Other preferred features, advantageous refinements, and improvements as well as advantages of a radiation-emitting component pursuant to the invention are found below in combination with the examples, of embodiment explained in detail with FIGS. 1 to 4.

The figures show:

FIGS. 1a and 1b, show a schematic cross-sectional view of a first example of embodiment of a radiation-emitting component pursuant to the invention with unbent (FIG. 1a) and bent (FIG. 1b) fastening device,

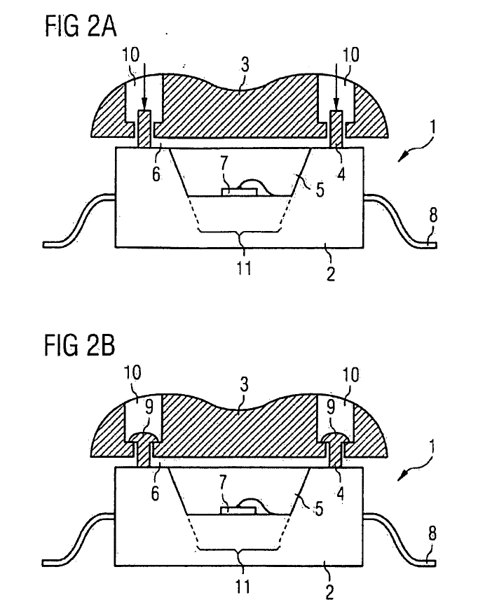

FIGS. 2a and 2b show a schematic cross-sectional view of a second example of embodiment of a radiation-emitting component pursuant to the invention that has a fastening device without projections (FIG. 2a) and with projections (FIG. 2b),

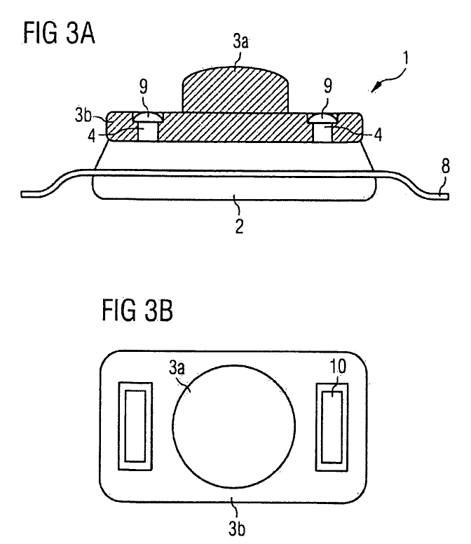

FIG. 3a shows a schematic side view and FIG. 3b a schematic top view of a third example of embodiment of a radiation-emitting component pursuant to the invention,

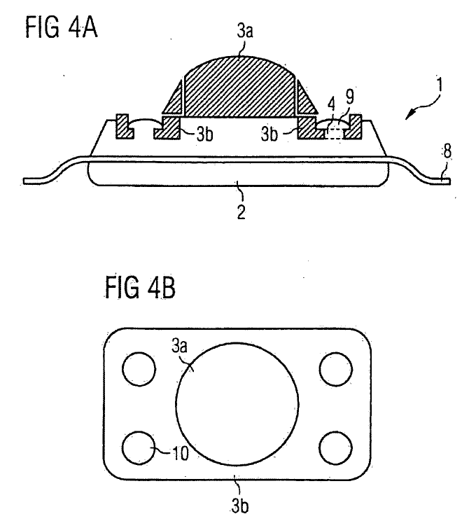

FIG. 4a shows a schematic view side view and FIG. 4b a schematic top view of a fourth example of embodiment of a radiation-emitting component pursuant to the invention.

FIG. 1a illustrates a radiation-emitting component 1 that comprises a housing body 2 and an optical element. The optical element, which is designed as a collecting lens, has a base 3a and a projection 3b encircling the base body 3a on its back face.

The optical element is placed on its back in a fastening device 4 that wraps around it. In particular, the fastening device 4 is made as a wall encircling the optical element 3 and has the cross section of a circular ring.

The fastening device is bent in the direction of the arrow so that the optical element is irreversibly fixed to the housing body 2.

The optical element is preferably separated from the housing body 2, so that the radiation-emitting component 1 has a gap 6. This has the advantage that the expansion of a shell 5 when heated can be compensated, which reduces the risk of stress cracks being formed, which can occur because of different coefficients of expansion of the housing body 2, the shell 5, and the optical element.

The shell 5 typically fills a recess 11. There is a radiation-emitting semiconductor body 7 in the recess 11, which is embedded in the shell 5. It is expedient for the shell 5 to comprise a material that is transparent to the radiation generated by the semiconductor body 7 and that is stable to degradation. A silicone or silicone resin are examples of suitable materials for short-wave radiation.

The recess 11 is preferably made with a funnel shape and is provided with a reflection-enhancing material. It can then contribute toward forming a beam. The recess 11 leaves open a radiation window 12 in the housing body 2, through which radiation emitted by the radiation-emitting semiconductor body 7 can reach the optical element.

The housing body 2 comprises a two-part conductor frame 8, with the semiconductor body 7 located on the back of a first part of the conductor frame and connected by a wire to a second part on the front face. The radiation-emitting component 1 can be connected by means of the conductor frame 8 to an electrical power supply.

FIG. 1b shows the bent fastening device 4, which grips the projection 3b of the optical element and thus prevents vertical motion of the optical element relative to the housing body 2. The bent fastening device 4 surrounds the optical element with a form fit.

The fastening device 4 is thermally formed. As described in the general part, this can be done by riveting. The fastening device 4 preferably comprises a thermoplastic material. The optical element, on the other hand, comprises a thermosetting plastic material and is dimensionally stable at the processing temperature used.

The embodiment of a radiation-emitting component 1 illustrated in FIGS. 2a and 2b, like the first example of embodiment, is made as an SMD component. In contrast to the first example of embodiment, of course, it has an optical element 3 covering the housing body 2.

The optical element 3 is a lens that consists of a concave lens at the center and a convex lens encircling the concave lens. It is possible with such a lens to distribute the radiant energy produced by the semiconductor body 7 over a relatively large space angle. The component 1 provided with the lens is especially suitable for homogeneous illumination, for example for backlighting displays.

The optical element 3 has recesses 10 that extend from the front to the back of the optical element 3. The recesses 10 are narrowed toward the back.

The fastening device 4 reaches into the back of the recesses 10. It comprises two peg-like fastening elements that just fit into the narrowed parts of the recesses 10.

The fastening device 4 is provided with projections in the direction of the arrows at its end facing the optical element 3, so that the optical element 3 is irreversibly fixed on the housing body 2.

As in the first example of embodiment there is a gap 6 between the optical element 3 and the housing body 2 that is provided to compensate for material expansion from heating, especially the material of the shell 5. The gap 6 can also be filled with a material that moderates a refractive index discontinuity at the interface between the housing body 2 and the optical element 3.

FIG. 2b shows the radiation-emitting component 1 illustrated in FIG. 2a after developing projections 9. These are shaped like a head and prevent the optical element 3 from slipping out of the fastening device 4 at the narrowed points. The projections 9, according to one of the methods described in the general part, are preferably made by thermal forming of the fastening device 4. The recesses can subsequently be filled with a material that has a refractive index corresponding to that of the optical element 3. The optical properties of the optical element 3 can be safeguarded in this way.

FIG. 3a illustrates a radiation-emitting component 1 whose housing body 2 has the elements corresponding to the first and second examples of embodiment (some not shown).

The fastening device 4 has two fastening elements, with both elements extending like combs on the housing body 2 that partly border the window 12. The optical element has fitting recesses 10 for the fastening device 4, as shown in FIG. 3b.

The optical element comprises a base body 3a and a base 3b with the recesses 10. The optical properties of the base body 3a are unaffected by the arrangement of the recesses 10 in the base 3b.

The optical element is preferably made in one piece by injection molding with the recesses 10 being left open during production. Alternatively, the recesses 10 can be introduced into the optical element after production.

As shown in FIG. 3a, the recesses 10 have a T-shaped cross section and are also elongated, as FIG. 3b shows.

The fastening device 4 engages in the recesses 10 and has projections 9 on the end racing the base body 3a, which are formed by thermal forming after the optical element and the housing body 2 are put together. The fastening device 4 and the projections 9 together produce a T-shape corresponding to the recesses 10.

In this example of embodiment the optical element and the housing body 2 are held together along two opposite-sides of the radiation-emitting component 1, so that especially stable fastening is obtained compared to point fixing by two pegs.

In the case of the radiation-emitting component 1 illustrated in FIGS. 4a and 4b, the fastening device 4 for has four peg-like fastening elements. These are embedded in the housing body 2. The base 3b can also be embedded in the housing body 2, so that the base body 3a reaches closer to the housing body than in the third example of embodiment.

The fastening elements have projections 9 on their end facing the base body 3a, which are preferably made by hot-pressing and fix the optical element irreversibly on the housing body 2.

The invention is not limited by the description with reference to the examples of embodiment. Instead, the invention comprises any new feature and any combination of features, which in particular includes any combination of features in the patent claims, even though this feature or this combination itself is not explicitly described in the patent claims or in the examples of embodiment.

This patent application claims the priority of German Patent Application 102005047063.7 and the priority of German Patent Application 102006032428.5, the disclosed contents of which are herewith incorporated by back reference.

1. A radiation-emitting component comprising an optical element and a housing body that has at least one fastening device that engages into the optical element or wraps around it, wherein the fastening device is bent or provided with projections in such a way that the optical element is irreversibly fixed to the housing body.

2. The radiation-emitting component of claim 1, wherein the fastening device has the shape of a wall that is bent in such a way that it encloses a projection of the optical element.

3. The radiation-emitting component of claim 2, wherein the cross section of the fastening device has the shape of a circular or polygonal ring.

4. The radiation-emitting component of claim 1, wherein the fastening device has peg-like or comb-like fastening elements.

5. The radiation-emitting component of claim 4, wherein the optical element has recesses matching the fastening device, into which the fastening device is plugged.

6. The radiation-emitting component of claim 5, wherein cavities in the recesses are at least partially filled with a material that has a refractive index corresponding to that of the optical element.

7. The radiation-emitting component pursuant to claim 1, wherein the optical element is attached spaced from the housing body.

8. The radiation-emitting component of claim 7, wherein a gap is formed between the housing body and the optical element to compensate for the thermal expansion of a shell.

9. The radiation-emitting component of claim 1, wherein the housing body comprises a thermoplastic material

10. The radiation-emitting component of claim 1, wherein the optical element is dimensionally stable.

11. The radiation-emitting component of claim 10, wherein the optical element comprises a thermosetting material.

12. The radiation-emitting component of claim 10, wherein the optical element comprises a silicone.

13. The radiation-emitting component of claim 10, wherein the optical element comprises an epoxide.

14. The radiation-emitting component of claim 1, wherein the optical element is a refractive element, a diffractive element, or a dispersive element.

15. The radiation-emitting component claim 1, wherein the fastening device is formed on the housing body.

16. The radiation-emitting component claim 1, wherein the fastening device is formed thermally.

17. The radiation-emitting component pursuant to claim 16, wherein the fastening device is formed by means of a forming punch.

18. A method for producing a radiation-emitting component that has an optical element and a housing body with a fastening device by the steps:
positioning the optical element relative to the housing body so that the fastening device engages with or wraps around the optical element,
forming the fastening device in such a way that the optical element, is irreversibly fixed on the housing body.

19. The method of claim 18, wherein the fastening device is bent or projections are formed on the fastening device in the second step.

20. The method of claim 19, wherein the fastening device is formed thermally.

21. The method of claim 20, wherein the fastening device is formed by riveting, hot-pressing, or tamping.

22. The method of claim 18, wherein the housing body is produced by means of injection molding, high-pressure die casting, or high-pressure injection molding.

23. The method of claim 18, wherein the housing body and the optical element are produced by 2K injection molding.

24. The method pursuant to of claim 18, wherein the optical element is produced by 2K, injection molding.
